(19) United States
(12) Patent Application Publication
(10) Pub. No.: US 2015/0158494 A1
(43) Pub. Date: Jun. 11, 2015

(54) METHOD AND APPARATUS FOR DETERMINING CARELESSNESS OF DRIVER

(71) Applicants: Hyundai Motor Company, Seoul (KR); Kia Motors Corporation, Seoul (KR); Hyundai Dymos Inc., Seosan-si (KR)

(72) Inventors: Byung Jae LEE, Gunpo-si (KR); Yong Soo CHANG, Seoul (KR); In Ho LEE, Hwaseong-si (KR); Tae Hyoung YANG, Seoul (KR); Hyun Seok SONG, Yeosu-si (KR); Taek Jun NAM, Seongnam-si (KR)

(73) Assignees: Hyundai Motor Company, Seoul (KR); Kia Motors Corporation, Seoul (KR); Hyundai Dymos Inc., Seosan-si (KR)

(21) Appl. No.: 14/476,212

(22) Filed: Sep. 3, 2014

(30) Foreign Application Priority Data
Dec. 10, 2013 (KR) 10-2013-0153156

(51) Int. Cl. B60W 40/08; G01R 27/26

(52) U.S. Cl. CPC B60W 40/08; G01R 27/2605

(57) ABSTRACT

A method and an apparatus for determining a carelessness of a driver may include detecting an object having an impedance substance by capacitive sensors provided in a headrest of a seat of a vehicle, detecting changes in electrostatic capacity by the capacitive sensors, measuring distance values between the object having the impedance substance and the capacitive sensors by using the changes in electrostatic capacity detected by the capacitive sensors, and determining whether the object having the impedance substance may be in a careless state by using the distance values.

### CROSS-REFERENCE TO RELATED APPLICATION

The present application claims priority to Korean Patent Application No. 10-2013-0153156, filed on Dec. 10, 2013, the entire contents of which is incorporated herein for all purposes by this reference.

### BACKGROUND

1. Field of the Invention

The present invention relates to a method and an apparatus for determining a carelessness of a driver. More particularly, the present invention relates to a method of determining a careless state of a driver by measuring a movement of a head of the driver using a capacitive sensor provided in a headrest.

2. Description of Related Art

The number of traffic accidents that occurred in 2011 in Korea was 221,711. Among them, about 14,000 accidents, i.e., 63.1% of the accidents, were due to negligence in keeping eyes forward. Further, the main causes of negligence in keeping eyes forward are watching DMB, using mobile phones, dozing off behind the wheel, and the like.

Thus, apparatuses for properly sending an alarm to a driver against such a situation are necessary, and are under development.

As an example of the technologies, there is known a technology that determines whether a driver is dozing off behind the wheel by using body characteristics during dozing off, in particular, a closing pattern of an eye of the driver, and generating an alarm sound when the driver is dozing off to call his or her attention.

The technology corresponds to a method of photographing a face of a person with a camera to acquire an image of the face, and finding out a location of an eye from the acquired face image to determine whether the drive is dozing off behind the wheel according to a separation between a border line of an upper eyebrow and a border line of a lower eyebrow.

Another technology includes an apparatus for detecting a movement of brain waves and an eyeball to recognize the dozing off or a fatigue degree of the driver.

However, the conventional apparatuses for determining a carelessness of a driver by using an image camera or a separate brain wave sensor require an excessive amount of calculations for processing an image signal or a brain wave signal.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY

Various aspects of the present invention are directed to providing a method and an apparatus for determining a carelessness of a driver by which a front gaze deviation situation can be determined by measuring a motion of a head of a driver with capacitive sensors.

Various aspects of the present invention are directed to providing a method and an apparatus for determining a carelessness of a driver by which an accident can be prevented in advance by informing the driver of an alarm if it is determined that the driver is in a careless state such as failing to gaze at the front side.

In an aspect of the present invention, a method of determining a carelessness of a driver, the method may include detecting an object having an impedance substance by capacitive sensors provided in a headrest of a seat of a vehicle, detecting changes in electrostatic capacity by the capacitive sensors, measuring distance values between the object having the impedance substance and the capacitive sensors by using changes in the electrostatic capacity detected by the capacitive sensors, and determining whether the object having the impedance substance is in a careless state by using the distance values.

The method may further include after detecting the object having the impedance substance by the capacitive sensors provided in the headrest of the seat of the vehicle, determining that the object having the impedance substrate is seated on the seat of the vehicle when the distance values between the capacitive sensors and the object having the impedance substance are within a preset distance value range for a present time period.

after determining whether the object having the impedance substance is in the careless state by using the distance values, the method may further include generating an alarm when it is determined that the object having the impedance substance is in the careless state.

Generating the alarm may include generating vibrations by the seat provided in the vehicle, blowing hot wind or cool wind through the seat provided in the vehicle, or sending an alarm sound through a speaker provided in the vehicle.

In determining whether the object having the impedance substance is in the careless state by using the distance values, it is determined that the object having the impedance substance is in the careless state when a distance value between the object having the impedance substance and one of the capacitive sensors that is measured by the one of the capacitive sensor decreases and a distance value between the object having the impedance substance and another of the capacitive sensors that is measured by the another of the capacitive sensor decreases.

In determining whether the object having the impedance substance is in the careless state by using the distance values, it is determined that the object having the impedance substance is in the careless state when both the distance values between the capacitive sensors and the object having the impedance substance increase.

In measuring the distance values between the object having the impedance substance and the capacitive sensors by using the changes in electrostatic capacity detected by the capacitive sensors, electrostatic capacities increase as distances between the object having the impedance substance become smaller and electrostatic capacities decrease as the distances between the object having the impedance substance become larger.

In another aspect of the present invention, an apparatus for determining a carelessness of a driver may include capacitive sensors provided in a headrest of a seat of a vehicle, a signal processor for measuring distance values between an object having an impedance substance and the capacitive sensors by using changes in electrostatic capacity measured by the capacitive sensors, an integrated controller for determining whether the object having the impedance substance is in a careless state by using the distance values measured by the signal processor, and an alarm unit for sending an alarm to the object having the impedance substance as the integrated controller determines that the object having the impedance substance is in the careless state.

The alarm unit may include a vibrator for generating vibrations in the seat of the vehicle, a temperature controller for blowing cool wind or hot wind to the seat of the vehicle to adjust a temperature of the seat of the vehicle, and an alarm sound generator for generating an alarm sound through a speaker provided in the vehicle.

The electrostatic capacities of the capacitive sensors increase as distances between the object having the impedance substance and the capacitive sensor become smaller, and the electrostatic capacities of the capacitive sensors decrease as the distances between the object having the impedance substance and the capacitive sensor become larger.

The integrated controller determines that the object having the impedance substance is in the careless state when a distance value between the object having the impedance substance and one of the capacitive sensors that is measured by the one of the capacitive sensors decreases and a distance value between the object having the impedance substance and another of the capacitive sensors that is measured by the another of the capacitive sensor decreases.

The integrated controller determines that the object having the impedance substance is in the careless state when both the distance values between the capacitive sensors and the object having the impedance substance increase.

The integrated controller determines that the object having the impedance substance is completely seated on the seat of the vehicle when the distance values between the capacitive sensors and the object having the impedance substance are in a preset distance value range in a preset time period.

As described above, the apparatus for determining a carelessness of a driver according to the present invention has the following effects.

First, since a carelessness situation of a driver can be determined using multi-channel capacitive sensors and the situation is alarmed, a safety of a driver can be protected.

Second, since a motion of a head of a driver is continuously measured, and when a head of a driver is located in a danger area where a neck of the driver can be severely damaged during an accident, it can be alarmed. Thus, a driver can be prevented from being damaged severely.

Third, an attention of a drive can be called to prevent an accident in advance through a vibrating function, a temperature control function, and an alarm sound provided in a seat of a vehicle.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a view schematically showing a situation in a vehicle by which the present invention is realized.

FIG. 2 is a view showing FIG. 1 more schematically.

FIG. 3 is an enlarged view showing the headrest provided with the electrostatic sensors.

FIG. 4 is a view showing yawing of motions of a head of a person.

FIG. 5 is a view showing pitching of motions of a head of a person.

FIG. 6 is a view showing rolling that is a unilateral motion of a head of a person.

FIG. 7 is a view showing a state in which the capacitive sensors are mounted to the headrest of the vehicle in the method and the apparatus of determining a carelessness of a driver according to the exemplary embodiments of the present invention.

FIG. 8 schematically shows a state of using the method and the apparatus for determining a carelessness of a driver according to the exemplary embodiments of the present invention.

FIG. 9 is a graph briefly depicting frequency values according to distances of capacitive sensors used in the method of determining a carelessness of a driver according to the exemplary embodiment of the present invention.

FIG. 10 is a view schematically showing a process of measuring a distance using two capacitive sensors in the method and the apparatus for determining a carelessness of a driver according to the exemplary embodiments of the present invention.

FIG. 11 is a view showing which location a head of a person is located a danger is recognized in the method and the apparatus for determining a carelessness of a driver according to the exemplary embodiments of the present invention.

FIG. 12 is a view showing a method of detecting rotation of a head of a person based on distance values measured by the capacitive sensors in the method and the apparatus for determining a carelessness of a driver according to the exemplary embodiments of the present invention.

FIG. 13 is a view showing that it is determined through magnitudes of frequencies measured by the capacitive sensors whether a person turns his or her head.

FIG. 14 is a view showing a range of a reference value for determining that a person is seated on a seat when he or she is seated first in the method and the apparatus for determining a carelessness of a driver according to the exemplary embodiments of the present invention.

FIG. 15 is a flowchart showing a process of the method and the apparatus for determining a carelessness of a driver according to the exemplary embodiments of the present invention.

FIG. 16 is a view schematically showing components of the apparatus for determining a carelessness of a driver according to the exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

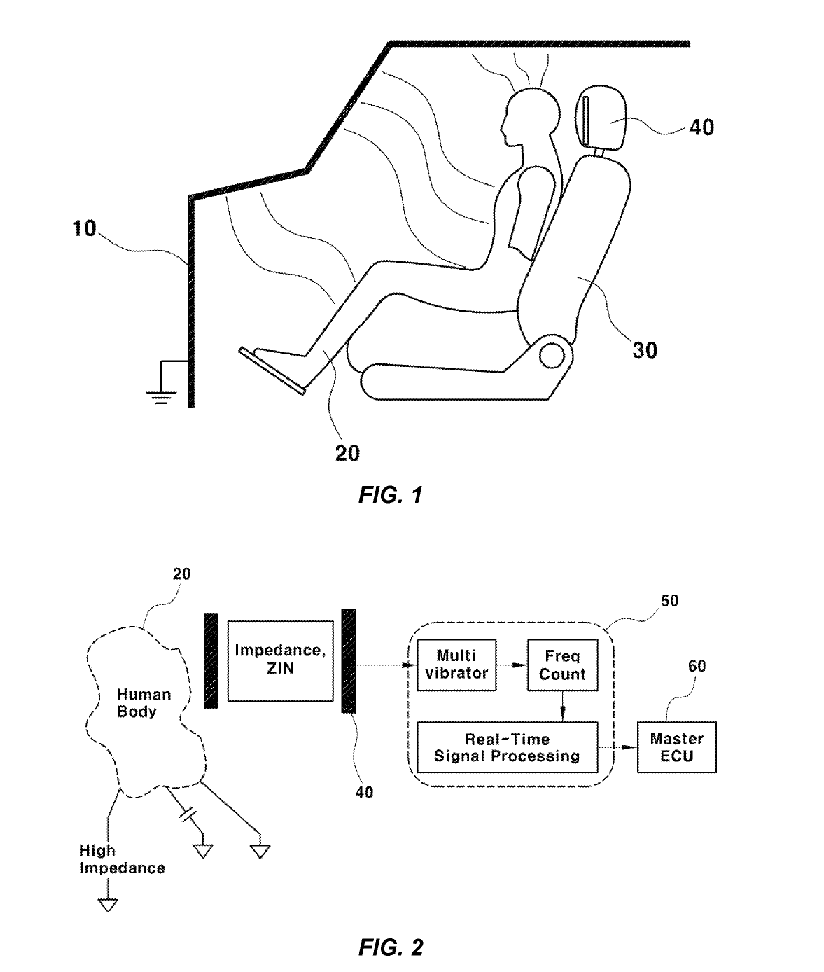

FIG. 1 is a view schematically showing a situation in a vehicle by which the present invention is realized.

In a method of determining a carelessness of a driver according to an exemplary embodiment of the present invention, capacitive sensors for detecting a change in electrostatic capacity may be provided at a portion of a headrest 40 of a seat 30.

The chassis of the vehicle 10 itself may be regarded as the ground.

A person seated on the seat 30 may be regarded as an object having an impedance substance of a large value.

Thus, in the method of determining a carelessness of a driver according to the exemplary embodiment of the present invention, a situation in which a person that is an object having an impedance substance does not currently stare a front side by detecting a separation between a head of the person and a headrest using a capacitive sensor.

FIG. 2 is a view showing FIG. 1 more schematically.

In FIG. 2, the body of a person is expressed as an object having an impedance substance of a large value. A change in electrostatic capacity may be detected by the capacitive sensors in the headrest 40. Briefly, the headrest 40 provided with the capacitive sensors and the head of the person may be regarded as electrodes, and an impedance values is changed by an electric charge induced according to a distance between the headrest 40 and the head of the person such that a distance between the capacitive sensors and the head of the person may be measured.

A signal processing system 50 may detect a change in frequency according to a change in electrostatic capacity, and may calculate the change in frequency into a distance value. Thereto, the signal processing system 50 may include a multi-vibrator, a frequency counter, and a real-time signal processor.

The signal processing system 50 may transmit a distance value obtained through the calculation result to a master ECU 60, and may determine a movement situation of the head by using a distance value measured by the capacitive sensors.

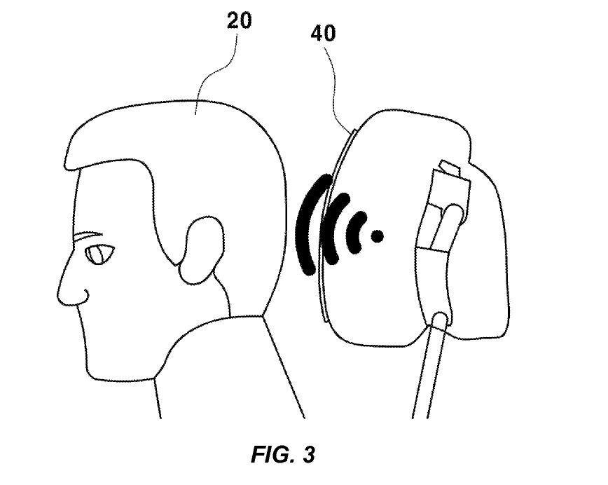

FIG. 3 is an enlarged view showing the headrest provided with the electrostatic sensors.

A headrest that is a safety apparatus for preventing a neck of a person from being instantaneously bent rearwards during a collision accident while prevent neck bones from being damaged may be located at a head of the person.

In the method and the apparatus for determining a carelessness of a driver according to the exemplary embodiments of the present invention, capacitive sensors 41 and 42 are mounted to a headrest 40 to measure a distance between a head 20 of the driver and the headrest 40.

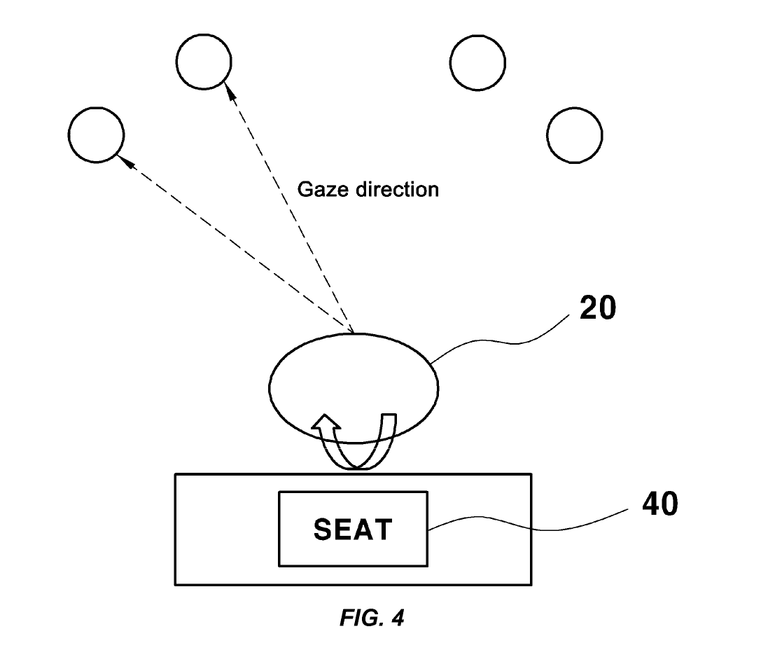

FIGS. 4 to 6 show a form in which a head of a person is moved with respect to a headrest of a seat of a vehicle.

FIG. 4 shows yawing of motions of a head of a person.

Yawing may teach an operation of moving a head of a person leftwards and rightwards. That is, through the operation, it may be recognized that a driver deviates from a forward gaze state and turns his or her head leftwards and rightwards.

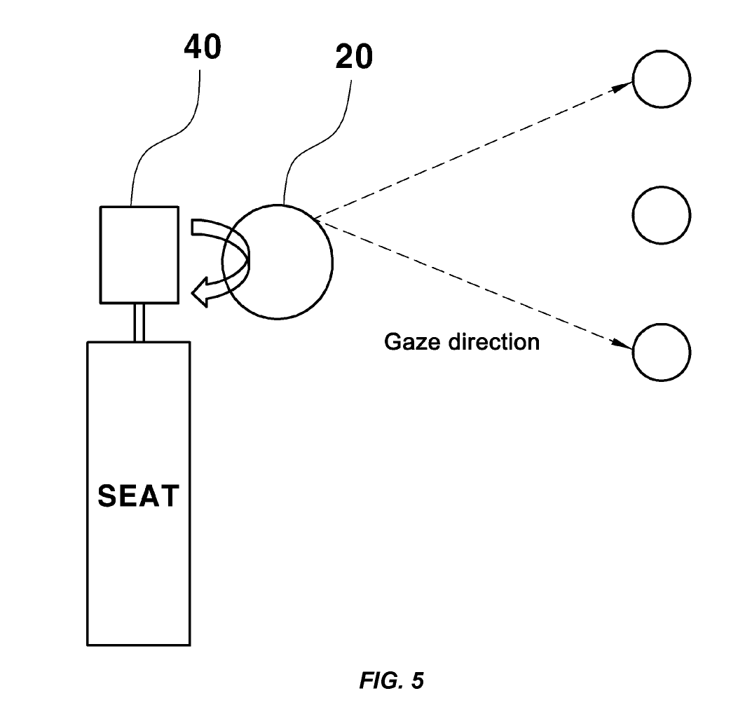

FIG. 5 shows pitching of motions of a head of a person.

Pitching may teach an operation of moving a head of a person upwards and downwards. That is, an operation of lowering a head of a driver may be detecting, and through the operation, it may be recognized that the driver is currently in a careless state for a front side by the method and the apparatus for determining a carelessness of the driver.

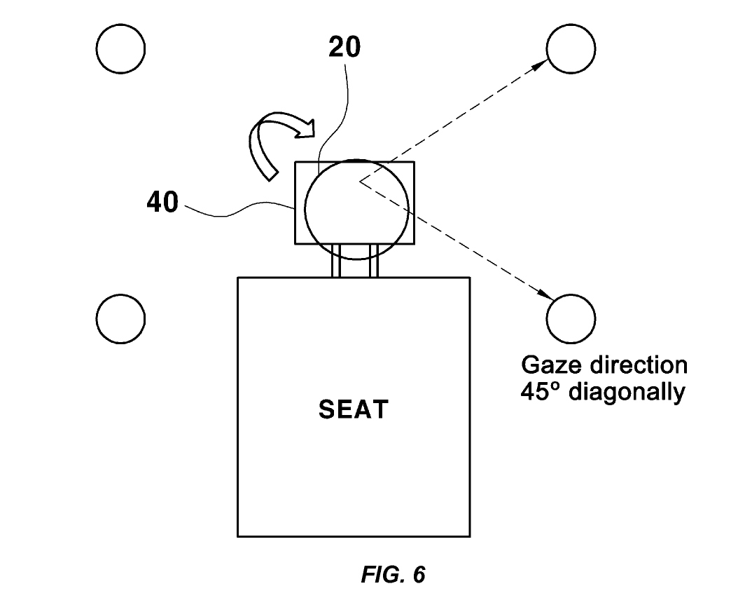

FIG. 6 is a view showing rolling that is a unilateral motion of a head of a person.

In FIG. 6, a unilateral motion may show an action of watching a landscape through a window of a door without gazing steadily at a front side of a driver.

In the method and the apparatus for determining a carelessness of a driver according to the exemplary embodiments of the present invention, a motion of the head of the driver may be determined by using the capacitive sensors mounted to the headrest and it may be determined whether the driver is in a carelessness state in which the driver does not gaze at a front side through the determination of the motion of the head.

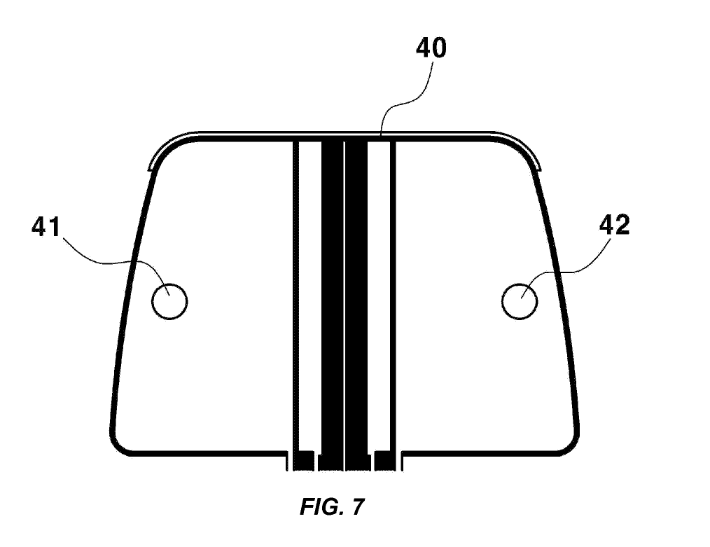

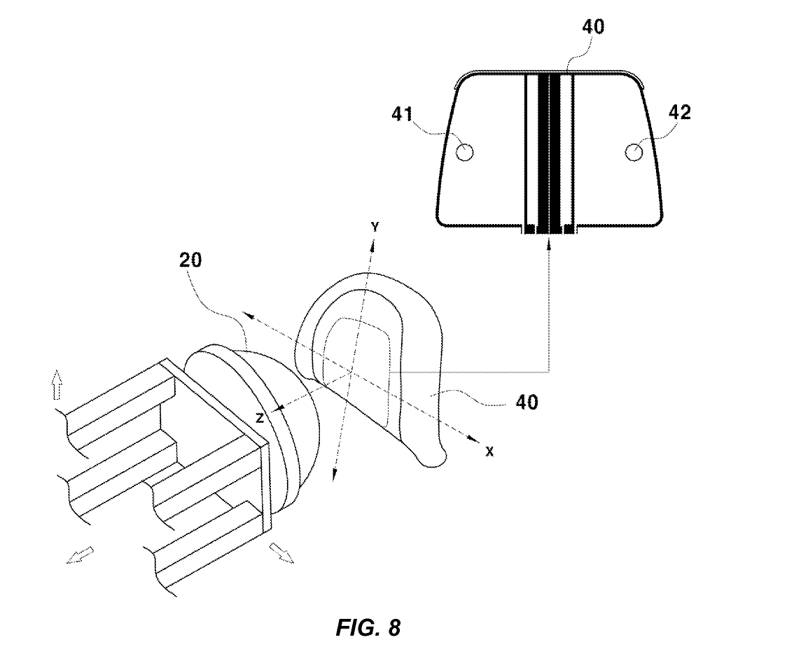

FIG. 7 is a view showing a state in which the capacitive sensors are mounted to the headrest of the vehicle in the method and the apparatus of determining a carelessness of a driver according to the exemplary embodiments of the present invention.

The headrest 40 for preventing a neck of a person from being bent during a collision of a vehicle may include a first capacitive sensor 41 and a second capacitive sensor 42. The first capacitive sensor 41 and the second capacitive sensor 42 may be provided at locations that are left-right symmetrical to each other with respect to the center of the headrest 40 such that a rotation of the head of the driver can be measured better.

Although two capacitive sensors are exemplified in the method and the apparatus for determining a carelessness of a driver according to the exemplary embodiments of the present invention, the present invention is not limited thereto but a suitable number of capacitive sensors may be installed in the headrest 40 of a seat of the vehicle.

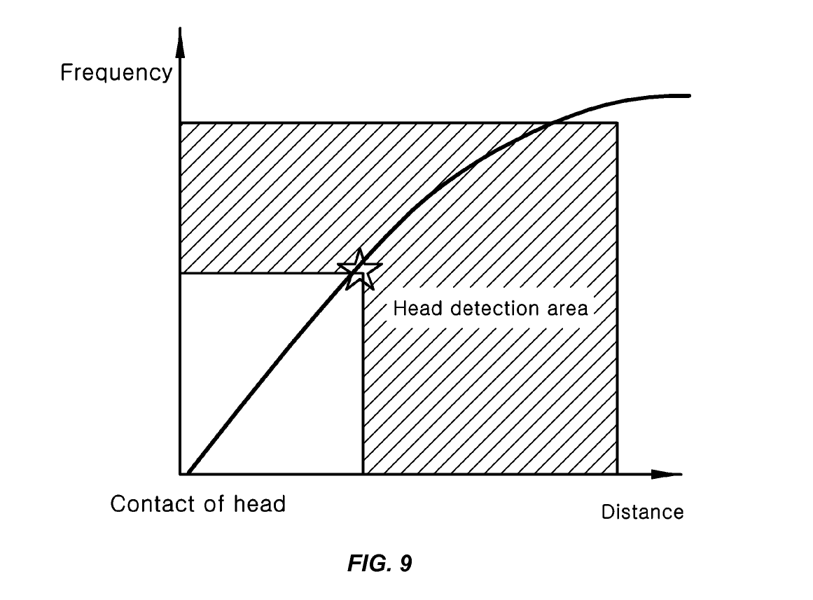

FIG. 8 schematically shows a state of using the method and the apparatus for determining a carelessness of a driver according to the exemplary embodiments of the present invention.

That is, a motion of the object 20 having an impedance substance with respect to the center of the headrest 40 may be observed through movements in three axial directions of the object 20. The left and right direction of the center of the headrest 40 may be determined as the X direction and the upward and downward direction of the headrest 40 may be determined as the Y direction. Further, the direction in which the object 20 faces from the headrest 40 toward the steering wheel may be determined as the Z direction.

Thus, in the method and the apparatus for determining a carelessness of a driver according to the exemplary embodiments of the present invention, it may be determined whether a driver currently gazes at a front side, by calculating movements of the object in the directions of the X, Y, and Z axes and measuring a three-dimensional movement of the object having an impedance substance.

FIG. 9 is a graph briefly depicting frequency values according to distances of capacitive sensors used in the method of determining a carelessness of a driver according to the exemplary embodiment of the present invention.

The capacitive sensor may detect a distance from an object that is to be measured through a change in electrostatic capacity. If a distance from an object that is to be measured becomes smaller, a frequency detected by the capacitive sensor may become lower, and if a distance from an object that is to be measured becomes larger, a frequency detected by the capacitive sensor may become higher.

This can be confirmed through an impedance formula of a capacitor, that is, 1/jωc. That is, if a distance from an object that is to be measured becomes larger, the value of c becomes smaller such that the value of co becomes larger. To the contrary, if a distance from an object that is to be measured becomes smaller, the value of c becomes larger such that the value of co becomes smaller.

FIG. 9 shows the principle of the capacitive sensor.

That is, it is shown that if a distance between the capacitive sensor and an object that is to be measured becomes larger, a magnitude of a frequency detected by the capacitive sensor increases.

However, a frequency value measured by the capacitive sensor in a predetermined range cannot represent an effective distance value between the capacitive sensor and an object that is to be measured.

Thus, since the frequencies in the range are not treated as effective data for measuring a distance between a head of a person and a capacitive sensor, only the frequencies higher than the range may be set as a head detection area.

The head detection area may be variously adjusted according to a performance of the capacitive sensor or a location of the capacitive sensor.

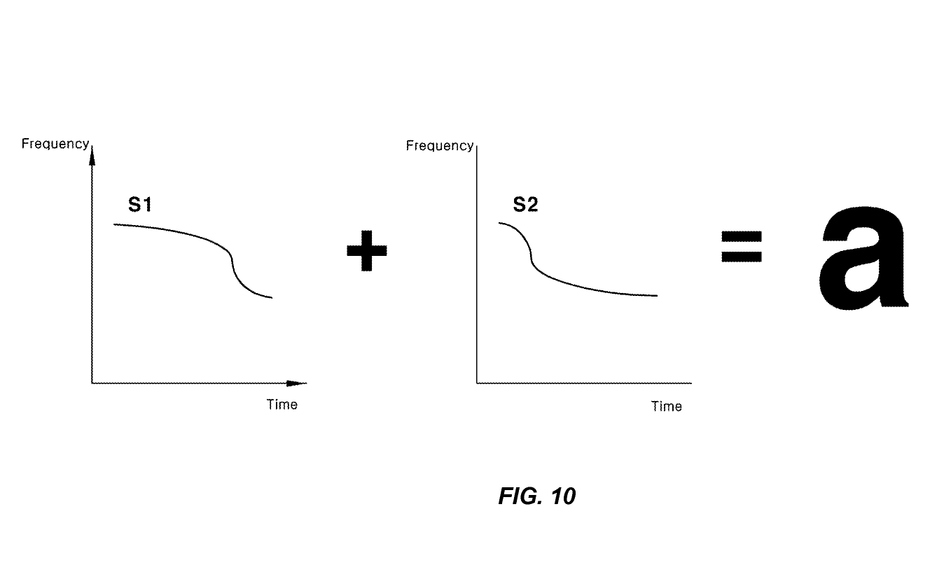

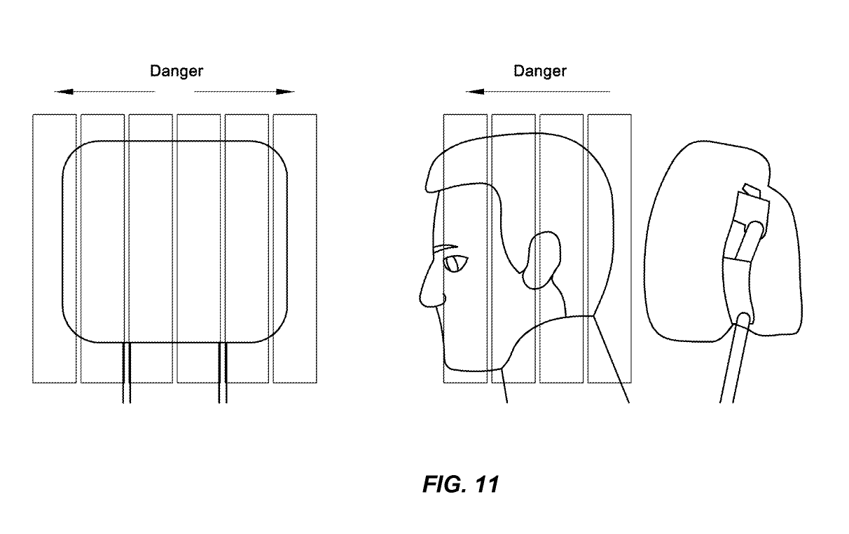

FIG. 10 is a view schematically showing a process of measuring a distance using two capacitive sensors in the method and the apparatus for determining a carelessness of a driver according to the exemplary embodiments of the present invention.

In FIG. 10, S1 may represent the first capacitive sensor and S2 may represent the second capacitive sensor.

It may be confirmed through FIG. 10 that the frequency measured by the first capacitive sensor decreases over time. This can represent that a distance between an object having an impedance substance and the first capacitive sensor becomes closer.

It may be confirmed that a distance between the second capacitive sensor and the object having an impedance substance becomes smaller more quickly that a distance between the first capacitive sensor and an object having an impedance substance.

In the method and the apparatus for determining a carelessness of a driver according to the exemplary embodiments of the present invention, a final distance between an object having an impedance substance, that is a head of a person and a headrest and a movement tendency of the head of the person may be determined through various combinations of the frequency values measured by the first capacitive sensor and the second capacitive sensor.

FIG. 11 is a view showing which location a head of a person is located and a danger is recognized in the method and the apparatus for determining a carelessness of a driver according to the exemplary embodiments of the present invention.

It may be generally determined that a person gazes at a front side if a head of the person is stuck to the center of the headrest. However, if the head of the person extensively deviates leftwards or rightwards, it cannot be determined through the operation that the person gazes at a front side properly.

Thus, in the method and the apparatus for determining a careless of a driver according to the exemplary embodiments of the present invention, a case in which a head of a person is situated at such a location may be determined to be a carelessness state.

A case in which a head of a person becomes gradually further from the headrest may also be determined that the person fails to gaze at the front side. The fact that the head of the person becomes gradually further from the headrest may mean that the driver lower his or her head due to sleepiness.

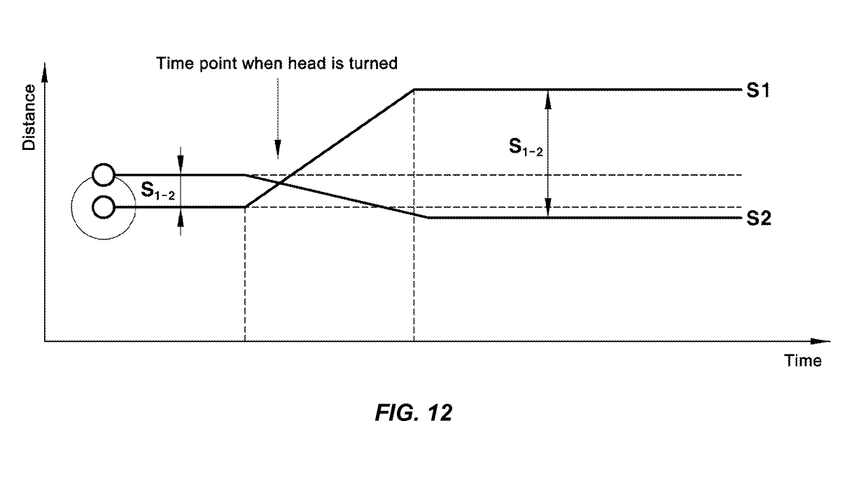

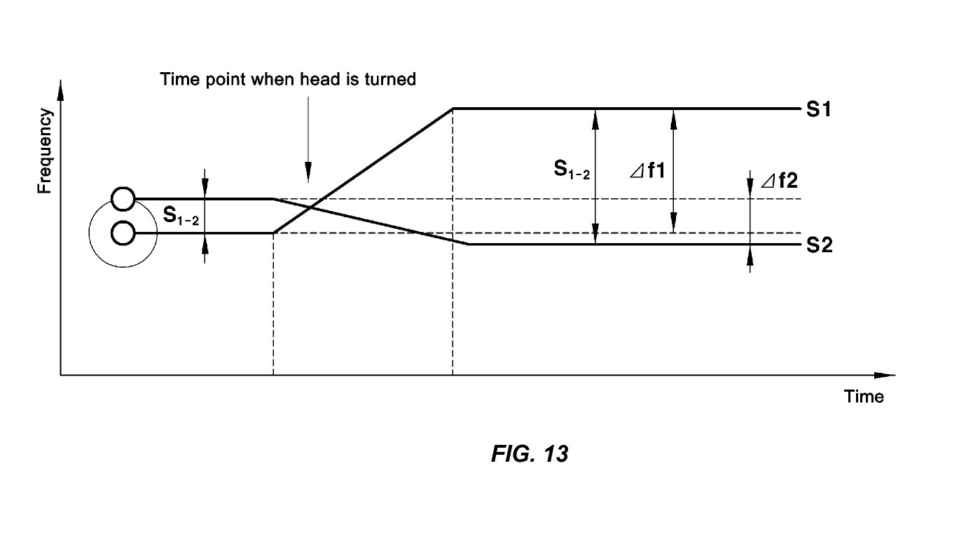

FIGS. 12 and 13 are graphs showing that a driver is currently turning his or her head through distances and frequency values measured by the capacitive sensors in the method and the apparatus for determining a carelessness of a driver according to the exemplary embodiments of the present invention.

FIG. 12 shows a method of detecting rotation of a head of a person based on distance values measured by the capacitive sensors in the method and the apparatus for determining a carelessness of a driver according to the exemplary embodiments of the present invention.

First, if S1 is the first capacitive sensor and S2 is the second capacitive sensor, it can be seen in the graph of FIG. 12 that a distance between the first capacitive sensor and the head of the person became larger and a distance between the second capacitive sensor and the head of the person became smaller. That is, it can be seen that the head of the person was rotated from the first capacitive sensor toward the second capacitive sensor. It may be determined that a point where a distance measured by the first capacitive sensor and a distance measured by the second capacitive sensor cross each other is a point where the person turns his or her head.

FIG. 13 is a view showing that it is determined through magnitudes of frequencies measured by the capacitive sensors whether a person turns his or her head.

It can be confirmed in FIG. 13 that a frequency value measured by the first capacitive sensor increased over time and a frequency value measured by the second capacitive sensor decreased over time. That is, it can be seen that a frequency value of the first capacitive sensor increased by Δf1 and a frequency value of the second capacitive sensor decreased by Δf2.

As discussed above, the capacitive sensors used in the method and the apparatus for determining a carelessness of a driver according to the exemplary embodiments of the present invention have characteristics in which a frequency increases as a distance from an object that is to be measured becomes larger.

Thus, it can be seen that a head of a person that is to be measured is rotated from the first capacitive sensor toward the second capacitive sensor since a frequency measured by the first capacitive sensor abruptly increases and a frequency measured by the second capacitive sensor decreases.

Further, it can be determined that a point where a frequency value measured by the first capacitive sensor and a frequency value measured by the second capacitive sensor cross each other is a point where a person turns his or her head.

In this way, although relationships between locations of the fist capacitive sensor and the second capacitive sensor, and an object having an impedance substance are illustrated through a separate graph according to distances and frequencies, they may correspond to each other.

It will be appreciated by those skilled in the art to which the present invention pertains that although a capacitive sensor a frequency of which increases as a distance between an object that is to be measured and the capacitive sensor becomes larger is used in the method and the apparatus for determining a carelessness of a driver according to the exemplary embodiments of the present invention, the capacitive sensor may be replaced by a capacitive sensor a frequency of which decreases as a distance between an object that is to be measured and the capacitive sensor becomes larger.

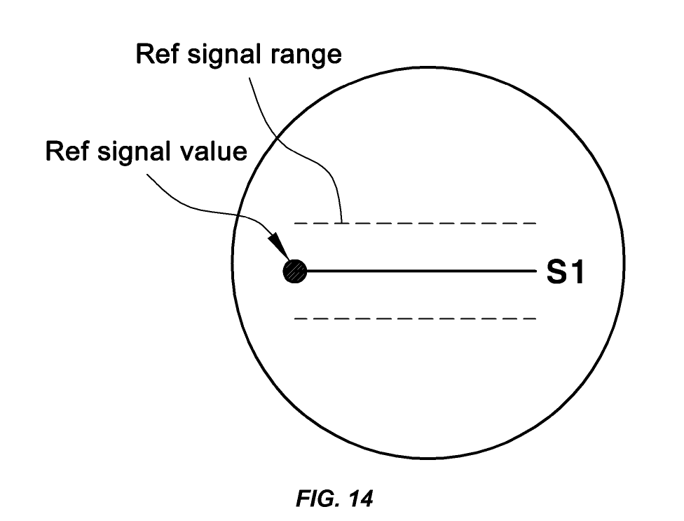

FIG. 14 is a view showing a range of a reference value for determining that a person is seated on a seat when he or she is seated first in the method and the apparatus for determining a carelessness of a driver according to the exemplary embodiments of the present invention.

If a person is seated in a vehicle first, he or she may perform rather distracted operations such as fastening a safety belt and turning on a navigation device.

Detecting and alarming all situations of a head of a driver may cause the driver to be excessively alarmed in a situation where the driver are not currently driving or cause a situation where an unnecessary alarm is generated.

In the method and the apparatus for determining a carelessness of a driver according to the exemplary embodiments of the present invention, in order to prevent such a situation, a motion of a head of a person is measured from a time point when the head is fixed to a stable location after the person is seated on the seat of the vehicle first.

Thus, in the method and the apparatus for determining a carelessness of a driver according to the exemplary embodiments of the present invention, it may be determined that a person has already been seated when distances between an object having an impedance substance and capacitive sensors are in a predetermined range and the predetermined range is maintained for a preset time period.

Thereto, a reference signal value is preset, and a range from the reference signal value may be set as a reference signal range.

Although it is illustrated that the reference signal and the reference signal range may be measured through a predetermined distance value, the present invention is not limited thereto but the reference signal may be replaced by a frequency value.

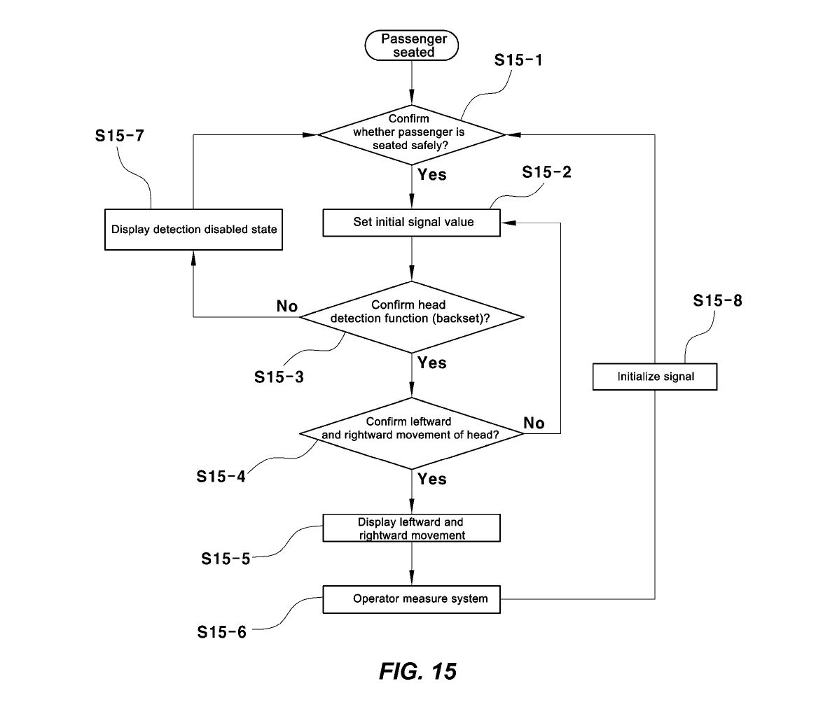

FIG. 15 is a flowchart showing a process of the method and the apparatus for determining a carelessness of a driver according to the exemplary embodiments of the present invention.

First, a person may be seated on a seat of a vehicle.

In the method of determining a carelessness of a driver according to the exemplary embodiment of the present invention, a process of determining whether a person is seated stably may be performed (S15-1). As discussed above, it may be confirmed through a reference signal value of FIG. 14. Further, it may be confirmed though a continuous input of a predetermined distance value. In addition, for example, it may be determined that the person is seated stably when a difference of continuous frequency values (distances) measured by the capacitive sensors for two seconds is maintained below a threshold value.

Next, a process of setting an initial signal value may be performed (S15-2). The process may be performed as a process for adjusting a sensitivity of a capacitive sensor. Thereto, an average of 100 sample frequency values or an average of sample frequency values for about 2 seconds may be set as an initial signal value.

Further, a process of confirming whether a head of a person can be detected may be performed based on the stable initial signal value (S15-3).

However, if a head of a person is not detected, the state is displayed as a detection disabled state through a display device (S15-7), and a step of confirming whether a person is stably seated may be performed again.

If a head of a person is detected, a process of detecting a motion of the head may be performed in the method of determining a carelessness of a driver according to the exemplary embodiment of the present invention may be performed (S15-4).

However, if a motion of the head of the person is not detected in this step, the sensitivity of the capacitive sensors has a problem. Thus, a process of setting an initial value of a signal of the capacitive sensor may be performed again.

However, when a movement of the head of the person is normally detected, a process of displaying a result obtained by measuring a leftward and rightward motion of the head of the person through a display device may be performed next (S15-5). Further, a process of determining whether the motion of the head of the person currently represents a carelessness situation of the driver may be performed at the same time.

In the method of determining a carelessness of a driver according to the exemplary embodiment of the present invention, if it is determined that the driver is currently in a careless state as the motion of the head of the person is distracted in this step, a process of alarming a driver of the fact may be performed (S15-6).

Further, in the method of determining a carelessness of a driver according to the exemplary embodiment of the present invention, in order to perform a process of detecting a motion of the head of the person again, a process of initializing signals measured by the capacitive sensors may be performed (S15-8).

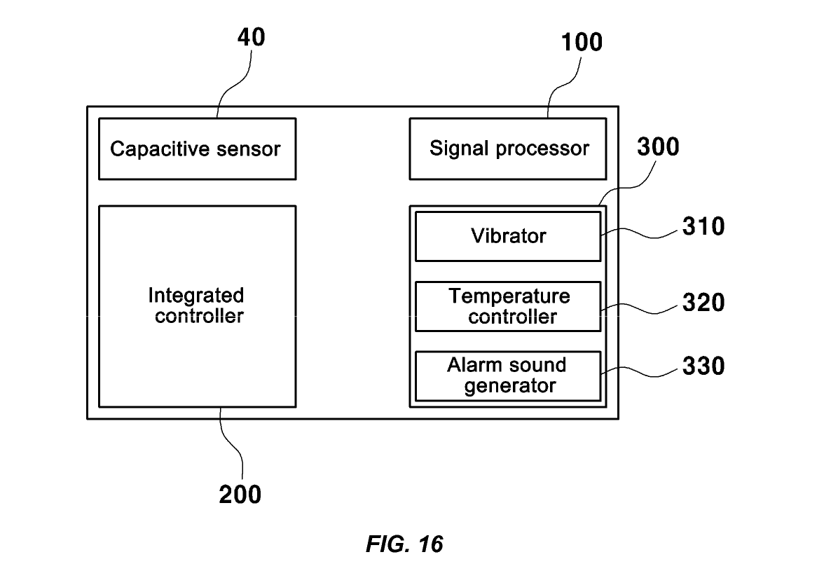

FIG. 16 is a view schematically showing components of the apparatus for determining a carelessness of a driver according to the exemplary embodiment of the present invention.

The apparatus for determining a carelessness of a driver according to the exemplary embodiment of the present invention may include capacitive sensors 41 and 42, an integrated controller 200, a signal processor 100, and an alarm unit 300.

The alarm unit 300 may include a vibrator 310, a temperature controller 320, and an alarm sound generator 330.

The capacitive sensors 41 and 42 may be mounted to the headrest 40 of the driver's seat of the vehicle. Two or more capacitive sensors 41 and 42 may be provided to be installed on opposite surfaces of the headrest 40 facing the head of the driver. The capacitive sensors 41 and 42 may serve to detect a change in electrostatic capacity according to a motion of the head of the person.

The signal processor 100 may serve to convert changes in electrostatic capacity measured by the capacitive sensors 41 and 42 into frequency values. That is, the electrostatic capacities measured by the capacitive sensors 41 and 42 may represent impedance values, and the impedance values may be converted into frequency data by the signal processor 100.

The integrated controller 200 may serve to determine whether the driver is currently in a careless state by combining the signal based on the frequency data converted by the signal processor 100. Thereto, the integrated controller 200 may include a determination algorithm for analyzing a frequency data signal converted by the signal processor 100 to determine a motion of the head of the driver.

As the integrated controller 200 determines that the driver is currently in a careless state, the alarm unit 300 may take a measure for calling a proper attention to the driver.

The vibrator 310 of the alarm unit 300 may generate vibrations in the seat of the driver to call an attention to the driver. The temperature controller 320 of the alarm unit 300 may blow hot wind or cool wind to the seat of the driver to wipe the sleep. Further, the alarm sound generator 330 of the alarm unit 300 may send an alarm sound to the driver by using a speaker mounted to the vehicle to call an attention to the driver.

In addition, the apparatus for determining a carelessness of a driver according to the exemplary embodiment of the present invention may include a graphic user interface (GUI) system for transmitting an alarm message or a signal determined by the integrated controller 200 by using a display device mounted to the vehicle.

For convenience in explanation and accurate definition in the appended claims, the terms “upper”, “lower”, “inner” and “outer” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A method of determining a carelessness of a driver, the method comprising:
detecting an object having an impedance substance by capacitive sensors provided in a headrest of a seat of a vehicle;
detecting changes in electrostatic capacity by the capacitive sensors;
measuring distance values between the object having the impedance substance and the capacitive sensors by using changes in the electrostatic capacity detected by the capacitive sensors; and
determining whether the object having the impedance substance is in a careless state by using the distance values.

2. The method of claim 1, further comprising:
after detecting the object having the impedance substance by the capacitive sensors provided in the headrest of the seat of the vehicle, determining that the object having the impedance substrate is seated on the seat of the vehicle when the distance values between the capacitive sensors and the object having the impedance substance are within a preset distance value range for a present time period.

3. The method of claim 1, further comprising:
after determining whether the object having the impedance substance is in the careless state by using the distance values, generating an alarm when it is determined that the object having the impedance substance is in the careless state.

4. The method of claim 3, wherein generating the alarm comprises:
generating vibrations by the seat provided in the vehicle;
blowing hot wind or cool wind through the seat provided in the vehicle; or
sending an alarm sound through a speaker provided in the vehicle.

5. The method of claim 1, wherein in determining whether the object having the impedance substance is in the careless state by using the distance values, it is determined that the object having the impedance substance is in the careless state when a distance value between the object having the impedance substance and one of the capacitive sensors that is measured by the one of the capacitive sensor decreases and a distance value between the object having the impedance substance and another of the capacitive sensors that is measured by the another of the capacitive sensor decreases.

6. The method of claim 1, wherein in determining whether the object having the impedance substance is in the careless state by using the distance values, it is determined that the object having the impedance substance is in the careless state when both the distance values between the capacitive sensors and the object having the impedance substance increase.

7. The method of claim 1, wherein in measuring the distance values between the object having the impedance substance and the capacitive sensors by using the changes in electrostatic capacity detected by the capacitive sensors, electrostatic capacities increase as distances between the object having the impedance substance become smaller and electrostatic capacities decrease as the distances between the object having the impedance substance become larger.

8. An apparatus for determining a carelessness of a driver, the apparatus comprising:
capacitive sensors provided in a headrest of a seat of a vehicle;
a signal processor for measuring distance values between an object having an impedance substance and the capacitive sensors by using changes in electrostatic capacity measured by the capacitive sensors;
an integrated controller for determining whether the object having the impedance substance is in a careless state by using the distance values measured by the signal processor; and
an alarm unit for sending an alarm to the object having the impedance substance as the integrated controller determines that the object having the impedance substance is in the careless state.

9. The apparatus of claim 8, wherein the alarm unit comprises:
a vibrator for generating vibrations in the seat of the vehicle;
a temperature controller for blowing cool wind or hot wind to the seat of the vehicle to adjust a temperature of the seat of the vehicle; and
an alarm sound generator for generating an alarm sound through a speaker provided in the vehicle.

10. The apparatus of claim 8, wherein the electrostatic capacities of the capacitive sensors increase as distances between the object having the impedance substance and the capacitive sensor become smaller, and the electrostatic capacities of the capacitive sensors decrease as the distances between the object having the impedance substance and the capacitive sensor become larger.

11. The apparatus of claim 8, wherein the integrated controller determines that the object having the impedance substance is in the careless state when a distance value between the object having the impedance substance and one of the capacitive sensors that is measured by the one of the capacitive sensors decreases and a distance value between the object having the impedance substance and another of the capacitive sensors that is measured by the another of the capacitive sensor decreases.

12. The apparatus of claim 8, wherein the integrated controller determines that the object having the impedance substance is in the careless state when both the distance values between the capacitive sensors and the object having the impedance substance increase.

13. The apparatus of claim 8, wherein the integrated controller determines that the object having the impedance substance is completely seated on the seat of the vehicle when the distance values between the capacitive sensors and the object having the impedance substance are in a preset distance value range in a preset time period.
